(19) United States
(12) Patent Application Publication
(10) Pub. No.: US 2011/0006349 A1
(43) Pub. Date: Jan. 13, 2011

(54) FIELD EFFECT TRANSISTOR HAVING CHANNEL SILICON GERMANIUM

(75) Inventors: Hiroyuki Ota, Yokohama (JP); Vincent Sih, Singapore (SG)

Correspondence Address: TUROCY & WATSON, LLP, 127 Public Square, 57th Floor, Key Tower, CLEVELAND, OH, 44114, US

(73) Assignees: TOSHIBA AMERICA ELECTRONIC COMPONENTS, INC., Irvine, CA (US); CHARTERED SEMICONDUCTOR MANUFACTURING, LTD, Singapore (SG)

(21) Appl. No.: 12/501,718

(22) Filed: Jul. 13, 2009

(51) Int. Cl. H01L 29/78; H01L 21/336

(52) U.S. Cl. 257/288; 438/285; 257/E29.255; 257/E21.409

(57) ABSTRACT

Field effect transistors and methods of making field effect transistors are provided. The field effect transistor can contain a semiconductor substrate containing shallow trench isolations; a silicon germanium layer in a trench at an upper surface of the semiconductor substrate between the shallow trench isolations; a gate feature on the silicon germanium layer; and metal silicides on the upper potions of silicon germanium layer and semiconductor substrate that are not covered by the gate feature. The silicon germanium layer has a bottom surface and a top surface having a (100) plane and side surfaces having two or more planes.

### TECHNICAL FIELD

The following description relates generally to field effect transistors having a channel silicon germanium layer and methods of making field effect transistors having a channel silicon germanium layer.

### BACKGROUND

A logic gate performs a logical operation on one or more logic inputs and produces a single logic output. In electronic logic, a logic level is represented by a voltage or current, which depends on the type of electronic logic in use. Each logic gate requires power so that it can source and sink currents to achieve the correct output voltage.

NAND and NOR logic gates are the two pillars of logic. Other types of Boolean logic gates (e.g., AND, OR, NOT, XOR, XNOR) can be created from a suitable network of NAND or just NOR gate(s). They can be built from transistors that can create an inverter and a two-input AND or OR gate. Hence the NAND and NOR gates are called the universal gates.

Logic circuits include such devices as multiplexers, registers, arithmetic logic units (ALUs), and computer memory, all the way up through complete microprocessors which can contain more than a 100 million gates. In practice, the gates are made from field effect transistors (FETs). The field effect transistor is a type of transistor that relies on an electric field to control the shape and hence the conductivity of a channel of one type of charge carrier in a semiconductor material.

The channel of a FET is doped to produce either an N-type semiconductor or a P-type semiconductor, and is accordingly called a NFET or a PFET. The drain and source may be doped of opposite type to the channel, in the case of enhancement mode FETs, or doped of similar type to the channel as in depletion mode FETs. The most commonly used FET is a metal-oxide-semiconductor field effect transistor (MOSFET) or insulated-gate field effect transistor (IGFET).

### SUMMARY

The following presents a simplified summary of the information disclosed in the specification in order to provide a basic understanding of some aspects of the disclosed information. This summary is not an extensive overview of the disclosed information, and is intended to neither identify key or critical elements of the disclosed information nor delineate the scope of the disclosed information. Its sole purpose is to present some concepts of the disclosed information in a simplified form as a prelude to the more detailed description that is presented later.

One aspect of the innovation provides a field effect transistor. The field effect transistor can contain a semiconductor substrate containing source/drain regions and pocket regions therein; shallow trench isolations in the semiconductor substrate; a silicon germanium layer in a trench at an upper surface of the semiconductor substrate between the shallow trench isolations; a gate feature on the silicon germanium layer containing a gate insulating layer, a gate electrode, and side spacers; and metal silicides on the upper portions of silicon germanium layer and semiconductor substrate that are not covered by the gate feature. The silicon germanium layer has a bottom surface and a top surface having a (100) plane and side surfaces having two or more planes. The silicon germanium layer has no side surface under the gate feature in a direction of channel length.

Another aspect of the innovation relates another field effect transistor. The field effect transistor can contain a semiconductor substrate containing source/drain regions and pocket regions therein between shallow trench isolations; a silicon germanium layer in a trench at a substantially whole upper surface of the semiconductor substrate between the shallow trench isolations; a gate feature on the silicon germanium layer containing a gate insulating layer, a gate electrode, and side spacers; and metal silicides on the upper portions of silicon germanium layer and semiconductor substrate that are not covered by the gate feature. The silicon germanium layer has a bottom surface and a top surface having a (100) plane of and side surfaces having two or more planes.

Yet another aspect of the innovation provides methods of forming a field effect transistor. The method can involve forming a trench at a substantially whole upper portion of a semiconductor substrate between shallow trench isolations, the trench having a (100) plane of a bottom surface and (111) planes of side surfaces; heating the semiconductor substrate to change the (111) plane of the side surface of the trench to two or more different planes; forming a silicon germanium layer in the trench, the silicon germanium layer having a (100) plane of a bottom surface and a top surface and two or more planes of side surfaces; forming a gate feature containing a gate insulating layer, a gate electrode, and side spacers on the silicon germanium layer; forming source/drain regions and pocket regions in the semiconductor substrate; and forming metal silicides on the upper portions of silicon germanium layer and semiconductor substrate that are not covered by the gate feature.

The following description and the annexed drawings set forth certain illustrative aspects of the specification. These aspects are indicative, however, of but a few of the various ways in which the principles of the specification may be employed. Other advantages and novel features of the specification will become apparent from the following detailed description of the disclosed information when considered in conjunction with the drawings.

### BRIEF DESCRIPTION OF THE DRAWINGS

FIG. 1A is a top view of a portion of an exemplary field effect transistor in accordance with an aspect of the subject innovation.

FIG. 1B is a cross sectional view of a portion of an exemplary field effect transistor such as that taken along line X-X of FIG. 1A in accordance with an aspect of the subject innovation.

FIG. 1C is a cross sectional view of a portion of an exemplary field effect transistor such as that taken along line Y-Y of FIG. 1A in accordance with an aspect of the subject innovation.

FIGS. 2A-10A illustrate an exemplary methodology of forming a field effect transistor such as that taken along line X-X of FIG. 1A in accordance with an aspect of the subject innovation.

FIGS. 2B-10B illustrate an exemplary methodology of forming a field effect transistor such as that taken along line Y-Y of FIG. 1A in accordance with an aspect of the subject innovation.

FIG. 11 is a flow diagram of an exemplary methodology of forming a field effect transistor in accordance with an aspect of the subject innovation.

### DETAILED DESCRIPTION

The subject innovation described herein provides field effect transistors and manufacturing field effect transistors. In particular, the subject innovation provides field effect transistors having channel silicon germanium layer. The field effect transistor contains the silicon germanium layer between a semiconductor substrate and a gate feature.

The silicon germanium layer can have a bottom surface and a top surface having a (100) plane and side surfaces having two or more planes. The silicon germanium can have a substantially uniform height over a channel region of the field effect transistor. In one embodiment, the silicon germanium layer has no side surface at a portion of the semiconductor substrate that is covered with the gate feature in a direction of channel length. In another embodiment, the silicon germanium has all the side surfaces at portions of the semiconductor substrate that are not covered with the gate feature. The field effect transistor can improve one or more of on current (Ion) characteristics, linear drain current (Idlin) characteristics, and threshold voltage (Vth) characteristics because of the channel silicon germanium layer.

The field effect transistor can contain a semiconductor substrate containing source/drain regions and pocket regions therein and shallow trench isolations in the semiconductor substrate. The filed effect transistor can further contain a silicon germanium layer in a trench at an upper surface of the semiconductor substrate between the shallow trench isolations; a gate feature on the silicon germanium layer containing a gate insulating layer, a gate electrode, and side spacers; and metal silicides on the upper portions of silicon germanium layer and semiconductor substrate that are not covered by the gate feature.

In another embodiment, the field effect transistor contains a semiconductor substrate containing source/drain regions and pocket regions therein between shallow trench isolations and a silicon germanium layer in a trench at a substantially whole upper surface of the semiconductor substrate between the shallow trench isolations; a gate feature on the silicon germanium layer containing a gate insulating layer, a gate electrode, and side spacers. The field effect transistor can further contain metal silicides on the upper portions of silicon germanium layer and semiconductor substrate that are not covered by the gate feature. The silicon germanium layer has a bottom surface and a top surface having a (100) plane and side surfaces having two or more planes. The silicon germanium layer has no side surface under the gate feature in a direction of channel length.

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices may be shown in block diagram form in order to facilitate describing the claimed subject matter.

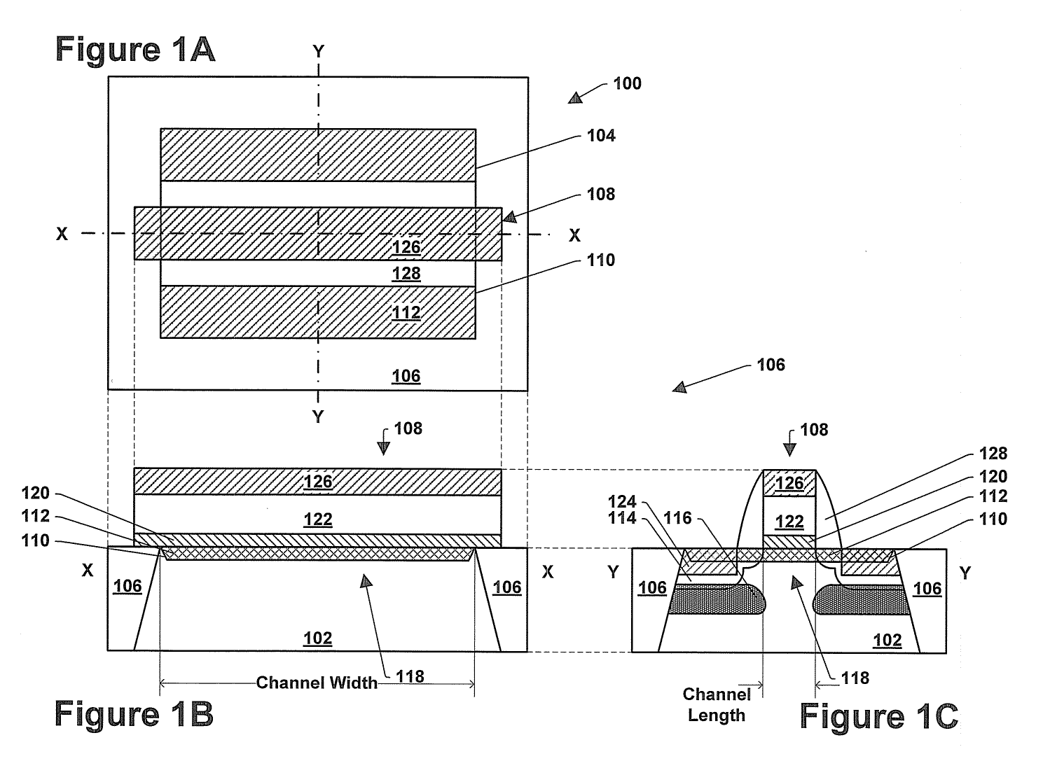

FIG. 1A illustrates a top view of a portion of an exemplary field effect transistor 100. FIG. 1B illustrates a cross sectional view of a portion of the field effect transistor 100, such as that taken along line X-X of FIG. 1A. FIG. 1C illustrates a cross sectional view of the field effect transistor 100, such as that taken along line Y-Y of FIG. 1A.

The field effect transistor has a semiconductor substrate (e.g., silicon substrate) 102. The field effect transistor contains an active region 104 in the semiconductor substrate between sallow trench regions (STIs) 106 and a gate feature 108 on the active region. The active region contains a trench 110 at the top surface of the semiconductor substrate and a silicon germanium layer 112 in the trench. The active region further contains source and drain (source/drain) regions 114, and pocket regions 116 in the semiconductor substrate. The active region contains a channel region 118 between the source and drain regions. The gate feature 108 contains a gate insulating layer 120 on the silicon germanium layer and a gate electrode 122 on the gate insulating layer. The field effect transistor can contain metal silicides 124 at the upper portions of the silicon germanium and semiconductor substrate. The gate feature can further contain metal silicides 126 at the upper portion of the gate electrode. The gate feature can further contain side spacers (side wall layers) 128 adjacent side surfaces of the gate insulating layer and the gate electrode feature. The field effect transistor can be p-type field effect transistor.

The field effect transistor has any suitable channel width. The channel width is generally a length of an active region in a longitudinal direction of the active region. The channel width is typically about 100 nm or more and about 2,000 nm or less. The field effect transistor has any suitable channel length. The channel length is generally defined between corresponding source/drain regions. The channel length is generally about 10 nm or more and about 100 nm or less.

In one embodiment, the trench 110 has no side surface under the gate feature in a direction of channel length (e.g., Y-Y direction). The trench has no side surface at a portion of the semiconductor substrate that is covered with the gate feature in a direction of channel length. The trench has all the side surfaces at portions of the semiconductor substrate that are not covered with the gate feature in a direction of channel length. In another embodiment, the trench has no side surface between corresponding source/drain regions.

In one embodiment, the silicon germanium layer 112 has no side surface under the gate feature in a direction of channel length. The silicon germanium has no side surface at a portion of the semiconductor substrate that is covered with the gate feature in a direction of channel length. The silicon germanium has all the side surfaces at portions of the semiconductor substrate that are not covered with the gate feature in a direction of channel length. In another embodiment, the silicon germanium layer has no side surface between corresponding source/drain regions.

Although not shown in FIG. 1 for brevity, the field effect transistor can contain any feature that can be normally employed in field effect transistor structures. For example, gate contact plugs, source-drain contacts, insulating layer between gate features, and the like can be further contained in the field effect transistor.

The trench 110 has a bottom surface and side surfaces. The bottom surface has a (100) plane (e.g., plane direction or plane orientation) or a plane equivalent thereto (e.g., (100), (010), or (001) plane) (referred to collectively hereinafter as “(100) plane”). The side surface of the trench can contain a (111) plane or a plane equivalent thereto (referred to collectively hereinafter as “(111) plane”) and other planes. The side surface does not substantially contain only a (111) plane. In other words, the side surface of the trench has two or more different planes.

The silicon germanium layer 112 has a bottom surface and a top surface. The bottom and top surfaces have a (100) plane. The silicon germanium layer further has side surfaces. The side surface of the silicon germanium layer can contain a (111) plane and other planes. The side surface of the silicon germanium does not substantially contain only a (111) plane. In other words, the side surface of the silicon germanium has two or more different planes.

The silicon germanium layer has any suitable amount of germanium as long as the amount of germanium can increase hole mobility in the channel region. In one embodiment, the silicon germanium layer contains about 0 wt. % or more and about 80 wt. % or less of silicon and about 20 wt. % or more and about 100 wt. % of germanium. In another embodiment, the silicon germanium layer contains about 30 wt. % or more and about 75 wt. % or less of silicon and about 25 wt. % or more and about 70 wt. % of germanium. In yet another embodiment, the silicon germanium layer contains about 60 wt. % or more and about 70 wt. % or less of silicon and about 30 wt. % or more and about 40 wt. % of germanium.

The source/drain region 114 can contain P-type conductivity (e.g., P dopant concentration such as boron). The pocket region can contain N-type conductivity (e.g., N dopant concentration such as arsenic, phosphorous, and antimony). The gate insulating layer 120 can contain any suitable inorganic oxide such as metal oxide or metalloid oxide (Hafnium oxide), silicon oxides (e.g., SiO₂), ceramic oxides, and the like. The gate electrode 122 can contains polysilicon, amorphous silicon, titan nitrides, and the like. The metal silicides 124, 126 can contain refractory metals, such as tungsten, tantalum, molybdenum and the like; and metals of Group VIII of the Periodic Table, such as platinum, palladium, cobalt, nickel, and the like. The side spacer and/or the STI can contain any suitable dielectric material such as oxides. Examples of oxides include silicon oxide, tetraethylorthosilicate (TEOS) oxide, high aspect ratio plasma (HARP) oxide, silicon oxide, high temperature oxide (HTO), high density plasma (HDP) oxide, oxides (e.g., silicon oxides) formed by an atomic layer deposition (ALD) process, and the like.

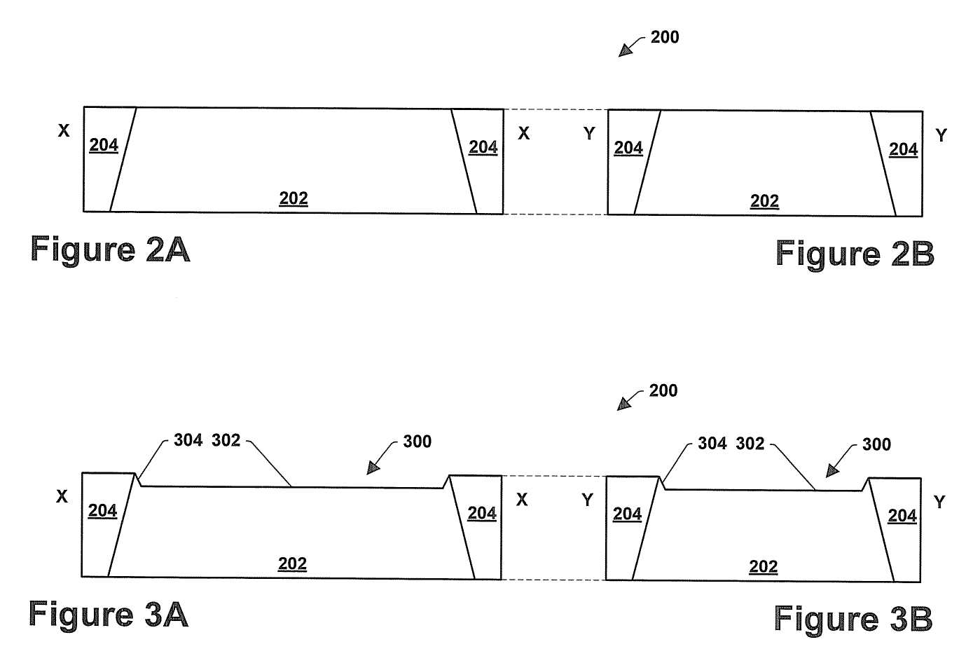

Referring to FIG. 2 to FIG. 10, one of many possible exemplary embodiments of forming a field effect transistor is specifically illustrated. FIG. 2A is a cross-sectional isometric illustration of an intermediate state of an exemplary field effect transistor 200, such as that taken along a line X-X of FIG. 1A. FIG. 2B is a cross-sectional isometric illustration of an intermediate state of an exemplary field effect transistor 200, such as that taken along a line Y-Y of FIG. 1A.

The field effect transistor 200 can contain a substrate (e.g., silicon substrate) 202 and STIs 204 in the semiconductor substrate. The STI can be formed by chemical vapor deposition (CVD), lithography, and etching techniques. A patterned hard mask is formed on the semiconductor substrate. Portions of the semiconductor substrate that are not covered by the patterned hard mask are removed by, for example, etching to make openings in the semiconductor substrate. The STI can be formed by filling the openings with the STI material.

Although not shown in FIGS. 2A and 2B, a well and a channel can be formed in the semiconductor substrate between the STIs. When the field effect transistor is PFET, a well is formed by implantation of one or more N dopants (e.g., phosphorus) and a channel is formed by implantation of one or more N dopants (e.g., arsenic).

FIGS. 3A and 3B illustrate forming a trench 300 at the top portion of the semiconductor substrate by removing portions of semiconductor substrate between the STIs. The trench can be formed at a substantially whole upper portion of the semiconductor substrate between shallow trench isolations. The trench can be formed by using an anisotropic chemical wet etching. When an oxide is formed on the semiconductor substrate before the anisotropic chemical wet etching, the oxide can be removed by using a diluted hydrofluoric acid (HF). The semiconductor substrate can be briefly dipped into the diluted HF.

The trench can be formed by any suitable anisotropic chemical wet etching as long as the etching forms a trench having a bottom surface 302 having a (100) plane. The anisotropic chemical wet etching generally forms a bottom surface of a (100) plane and side surfaces (e.g., side facets) 304 having a (111) plane.

Examples of etchants of anisotropic chemical wet etching include base solutions such as tetraallylammonium hydroxides (e.g., tetramethylammonium hydroxide (TMAH)) and ammonium hydroxide (NH₄OH). By way of example, forming a trench using a TMAH solution is described below. Forming the trench using the TMAH solution is typically administered by immersing the semiconductor structure 200 into the TMAH solution or spraying/spreading the TMAH solution over the top of the semiconductor structure 200.

The TMAH solution may contain a sufficient amount of TMAH to facilitate removing portions of the semiconductor structure 200 without substantially damaging or etching other components. In one embodiment, the TMAH solution contains about 0.5% of TMAH by weight or more and about 40% of TMAH by weight or less. In another embodiment, the TMAH solution contains about 1% of TMAH by weight or more and about 25% of TMAH by weight or less. TMAH may be diluted in water, such as de-ionized water, to produce the TMAH solution having a desired concentration of TMAH.

The semiconductor substrate 202 is contacted with the TMAH solution at a suitable temperature to facilitate forming the trench. In one embodiment, the semiconductor substrate is contacted with the TMAH solution at a temperature of about 20 degrees Celsius or more and about 100 degrees Celsius or less. In another embodiment, the semiconductor substrate is contacted with the TMAH solution at a temperature of about 30 degrees Celsius or more and about 60 degrees Celsius or less. The semiconductor substrate is contacted with the TMAH solution for a suitable time to facilitate forming the trench. In one embodiment, the semiconductor substrate is contacted with the TMAH solution for about 5 seconds or more and about 20 minutes or less. In one embodiment, the semiconductor substrate is contacted with the TMAH solution for about 10 seconds or more and about 15 minutes or less. For example, the semiconductor substrate is contacted with a TMAH solution that contains about 2.5% of TMAH by weight, at a temperature of about 45 degrees Celsius, for about 2.5 minutes.

In another embodiment, the etchant is a NH₄OH solution. NH₄OH may be diluted in water, such as de-ionized water, to produce the TMAH solution having a desired concentration of NH₄OH (e.g., NH₄OH:H₂O=1:3,000 (wt/wt)). The semiconductor substrate is contacted with a NH₄OH solution at a temperature of about 45 degrees Celsius, for about 100 seconds.

The trench 300 can have any suitable depth. The trench can have a substantially uniform depth. The depth may vary and may not be critical to the subject innovation. The depth may depend on, for example, the desired implementations of the field effect transistor being fabricated. In one embodiment, the depth of the trench is about 5 nm or more and about 20 nm or less. In another embodiment, the depth is about 6 nm or more and about 17 nm or less. In yet another embodiment, the depth is about 7 nm or more and about 15 nm or less. In still yet another embodiment, the depth is about 10 nm.

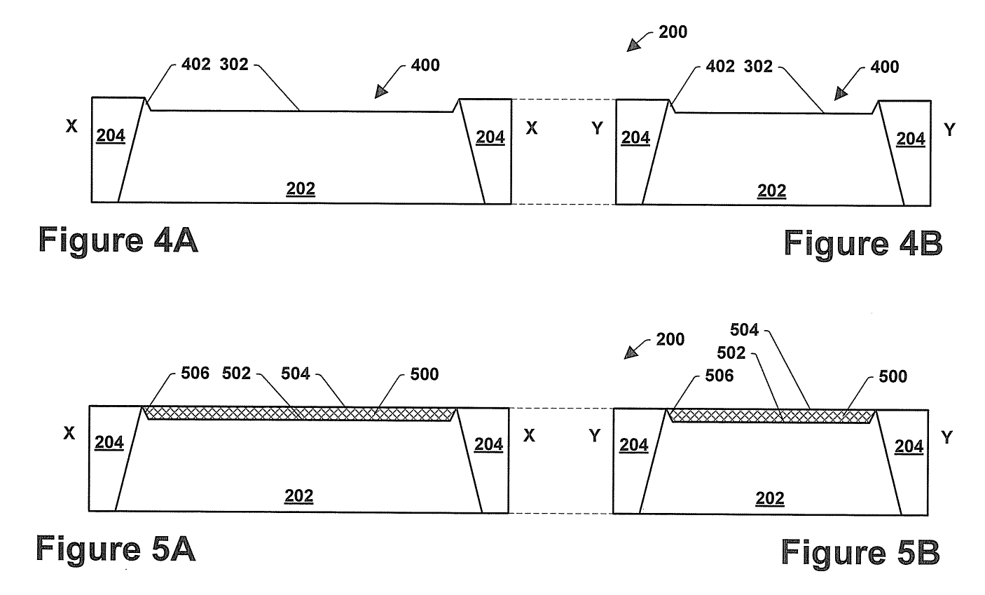

FIGS. 4A and 4B illustrate heating the semiconductor substrate to change a plane direction of the side surfaces of the trench. When the side surface has a single plane direction, the heat treatment changes the single plane direction to two or more plane directions. When the side surface has a single (111) plane, the heat treatment changes the single (111) plane to two or more planes containing, for example, a (111) plane, a (112) plane, a (200) plane, a (101) plane, a (011) plane, and the like. Due to the heat treatment, the trench 400 can have two or more planes of the side surfaces 402. The (100) plane of the bottom surface can be remained unchanged. The semiconductor substrate can be recrystallized by the heat treatment.

The semiconductor substrate 202 can be heated under any suitable condition to facilitate forming two or more planes of side surfaces of the trench and/or recrystallization of the semiconductor substrate. In one embodiment, the semiconductor substrate is heated in hydrogen at a temperature of about 700 degrees Celsius or more and about 900 degrees Celsius or less for about 1 minutes or more and about 10 minutes or less. In another embodiment, the semiconductor substrate is heated in hydrogen at a temperature of about 500 degrees Celsius or more and about 900 degrees Celsius or less for about 10 seconds or more and about 30 minutes or less.

FIGS. 5A and 5B illustrate forming a silicon germanium layer 500 in the trench. The silicon germanium layer can be formed by epitaxial technique. The silicon germanium epitaxial growth can proceed under any suitable condition, for example, at elevated temperatures (e.g., 1,100 degrees Celsius) using a silicon source gas (e.g., SiH₄, Si₂H₆, SiH₈, SiF₄, and the like), a germanium source gas (e.g., GeH₄, GeF₄, and the like), and optionally a carrier gas. The silicon germanium epitaxial growth can be terminated when the upper surface of the silicon germanium is substantially coplanar with the upper surfaces of the semiconductor substrate and/or STIs.

In one embodiment, the silicon germanium layer has a (100) plane of the bottom surface 502 when the trench has a (100) plane of the bottom surface. The silicon germanium layer can have a (100) plane of the top surface 504. In another embodiment, the silicon germanium layer has two or more different planes of side surfaces 506 when the trench has side surfaces having two or more different planes. In yet another embodiment, the silicon germanium layer has a substantially uniform height when the trench has a substantially uniform depth.

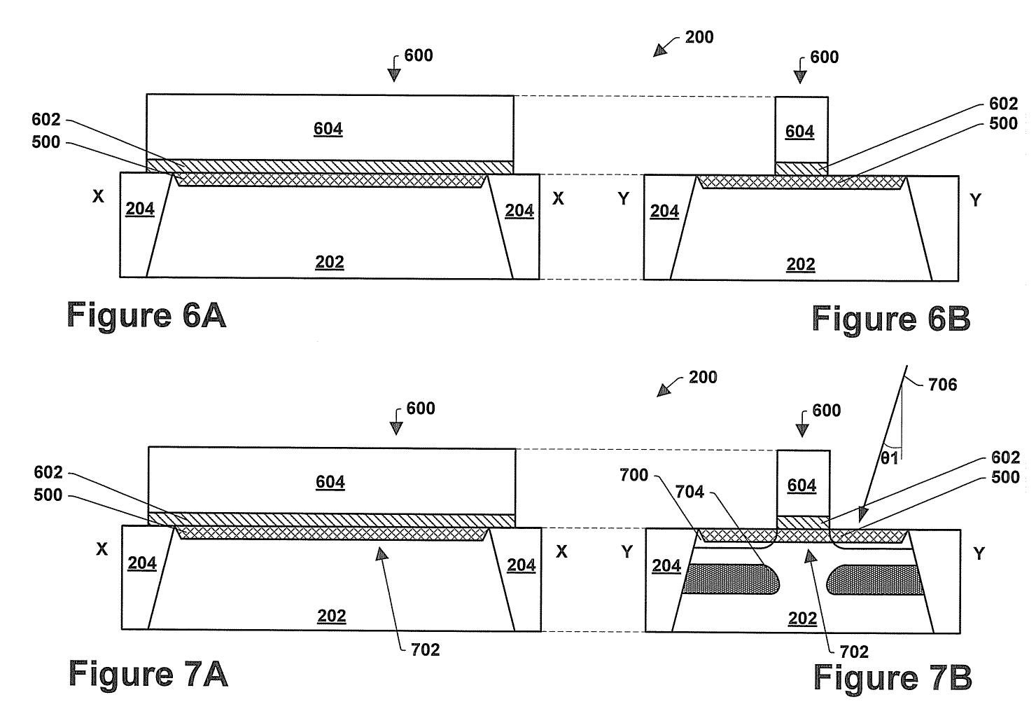

FIGS. 6A and 6B illustrate forming a gate feature 600 containing a gate insulating layer 602 and a gate electrode 604 on the silicon germanium layer 500. The gate feature can be formed by forming a gate insulating layer on the silicon germanium and a gate electrode layer on the gate insulating layer and patterning the gate insulating layer the gate electrode layer.

The gate insulating layer can contain any suitable inorganic oxide such as metal oxide or metalloid oxide (Hafnium oxide), silicon oxides (e.g., SiO₂), ceramic oxides, and the like. The gate electrode can contains polysilicon, amorphous silicon, titan nitrides, and the like. The gate insulating layer and the gate electrode can be formed by any suitable technique. For example, the gate insulating layer and the gate electrode can be formed by deposition (e.g., CVD, spin-on techniques, and the like), lithography, and etching techniques. The gate insulating layer can be formed by epitaxial growth techniques (e.g., silicon epitaxial growth) and oxidation techniques (e.g., thermal oxidation, plasma-assisted oxidation, and the like).

FIGS. 7A and 7B illustrate forming source/drain extension regions 700 in the semiconductor substrate adjacent the gate feature and forming a channel region 702 in the semiconductor substrate between the source/drain extension regions. Any suitable implant compositions and concentrations can be employed for the source/drain extension regions. For example, the source/drain extension regions include one or more p-type dopants (e.g., boron).

The source/drain extension region can be formed by any suitable technique. The source/drain extension region can be formed by implantation of one or more dopants. The dopants are implanted into the portions of semiconductor substrate that are not covered by the gate feature. The gate feature can serve as an implant screen. The source/drain extension region can be formed by implant with a relatively low energy level and/or a relatively low dose of dopants. In one embodiment, the source/drain extension region is formed at an energy level of about 0.1 KeV or more and about 1 KeV or less and a dose of about 1E14 atoms/cm² or more and about 3E15 atoms/cm² or less. In another embodiment, the source/drain extension region is formed at an energy level of about 1 KeV or more and about 5 KeV or less and a dose of about 5E13 atoms/cm² or more and about 3E15 atoms/cm² or less.

FIGS. 7A and 7B further illustrate forming pocket regions 704 in the semiconductor substrate adjacent and under the side surfaces of the gate feature. Any suitable implant compositions and concentrations can be employed for the pocket regions. For example, the pocket regions include one or more n-type dopants (e.g., arsenic). The pocket implant can improve Vth characteristics of the field effect transistor.

The pocket regions can have any suitable size, shape, implant composition, and concentration as long as the pocket region can improve contact punch-though leakage characteristics of the memory device. In one embodiment, the pocket regions have a tilt implant angle of about 0 degrees or more and about 40 degrees or less in the direction of the semiconductor substrate from an axis which is perpendicular to the surface of the semiconductor substrate. The pocket region can be formed by implantation of one or more dopants at any suitable implantation angle. The dopants are implanted at an angle θ1, shown as arrow 706, towards the semiconductor substrate. The angle θ1 is measured away from a line normal to the surface of the semiconductor substrate, as shown in FIG. 7B.

In one embodiment, the pocket region is formed at an energy level of about 25 KeV or more and about 60 KeV or less. In another embodiment, the pocket region is formed at an energy level of about 30 KeV or more and about 70 KeV or less. In one embodiment, the pocket region is formed at a dose of about 5E12 atoms/cm² or more and about 8E13 atoms/cm² or less. In another embodiment, the pocket region is formed at a dose of about 5E12 atoms/cm² or more and about 1E14 atoms/cm² or less.

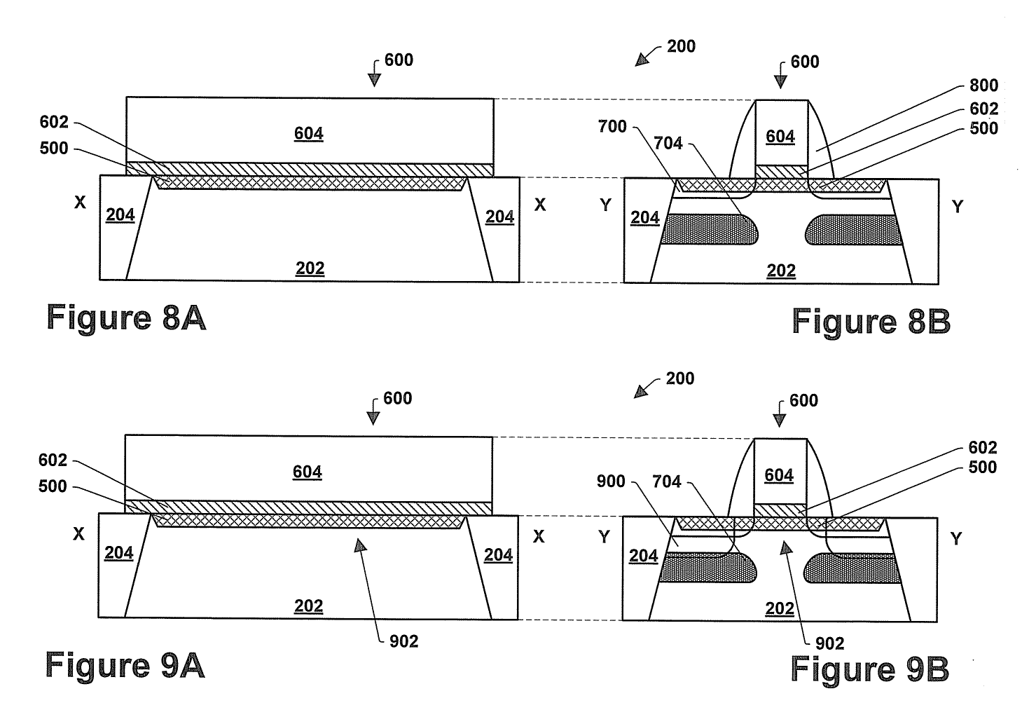

FIGS. 8A and 8B illustrate forming side spacers (e.g., side wall layers) 800 adjacent the side surfaces of the gate insulating layer and the gate electrode and on the upper surface of the silicon germanium layer 500. The side spacer can contain any suitable insulating material such as oxides. Examples of oxides include silicon oxide, tetraethylorthosilicate (TEOS) oxide, high aspect ratio plasma (HARP) oxide, high temperature oxide (HTO), high density plasma (HDP) oxide, oxides (e.g., silicon oxides) formed by an atomic layer deposition (ALD) process, and the like. Other examples of side spacer materials include nitrides (e.g., silicon nitride, silicon oxynitride, and silicon rich silicon nitride), silicates, diamond-like carbon, carbide, and the like. Although not shown, the source/drain extension regions and/or pocket regions can be formed after forming the side spacer.

The side spacer can be formed by any suitable technique, for example, forming a layer containing the spacer material over the semiconductor substrate and then removing portions of the spacer material layer not near the side surface of the gate feature. The spacer material layer can be formed by deposition technique (e.g., CVD, spin-on techniques, and the like) at least over the side surface of the gate feature.

After forming the spacer material layer, portions of the spacer material layer can be removed, for example, etching. Any suitable etching can be used as long as the etching can leave a spacer adjacent the side surfaces of the gate insulating layer and gate electrode and on the silicon germanium layer. Wet etching and/or dry etching can be employed. Examples of etching include reactive ion etching (RIE), chemical plasma etching, or other suitable anisotropic etching utilizing a suitable chemistry.

FIGS. 9A and 9B illustrate forming source/drain regions 900 in the semiconductor substrate adjacent the gate feature and forming a channel region 902 in the semiconductor substrate between the source/drain regions. Any suitable implant compositions and concentrations can be employed for the source/drain regions. For example, the source/drain regions include one or more p-type dopants (e.g., boron). Although not shown in FIGS. 9A and 9B, the implanted dopants can be activated by annealing the semiconductor substrate.

The source/drain region 900 can be formed by any suitable technique. The source/drain region can be formed by implantation of one or more dopants. The dopants are implanted into the portions of semiconductor substrate that are not covered by the gate feature and the side spacer. The gate feature and the side spacer can serve as an implant screen. The source/drain region can be formed by implant with a relatively high energy level and/or a relatively high dose of dopants. In one embodiment, the source/drain region is formed at an energy level of about 5 KeV or more and about 20 KeV or less and a dose of about 8E14 atoms/cm² or more and about 1E16 atoms/cm² or less. In another embodiment, the source/drain region is formed at an energy level of about 2 KeV or more and about 8 KeV or less and a dose of about 1E14 atoms/cm² or more and about 1 μl 6 atoms/cm² or less. In still another embodiment, the source/drain region 900 can be formed by embedded epitaxial SiGe. The dopants can be formed by in-situ doped epitaxial.

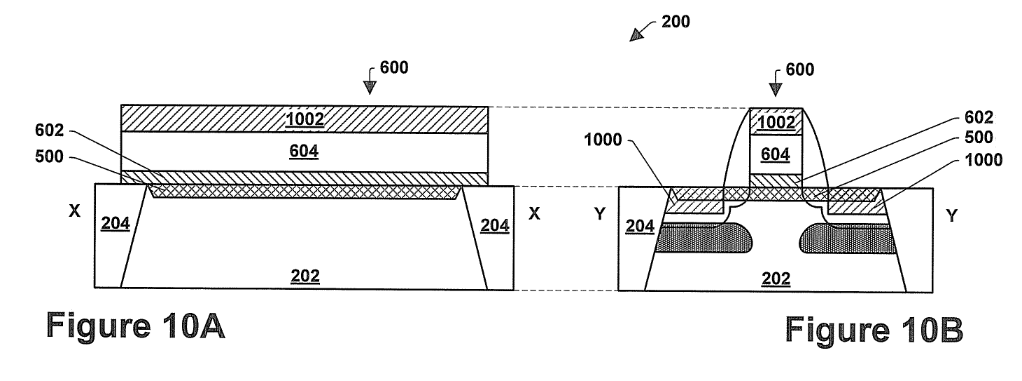

FIGS. 10A and 10B illustrate forming metal silicides 1000 on the portions of the silicon germanium and semiconductor substrate that are not covered by the gate feature (e.g., the gate feature and the side spacer). When the gate electrode contains silicon, metal silicides 1002 are formed on the gate electrode. The metal silicides can be formed by a chemical reaction of a metal layer formed over the field effect transistor with portions of the field effect transistor that are not covered by the gate feature. Metal silicides are not formed where the metal layer is not contacted with silicon containing layers/components of the field effect transistor.

Although not shown in FIGS. 10A and 10B, a metal layer is formed over the field effect transistor. The metal layer can contain any suitable metal compound that can be converted to metal silicides in a subsequent process. Examples of metals include refractory metals, such as tungsten, tantalum, molybdenum and the like; and metals of Group VIII of the Periodic Table, such as platinum, palladium, cobalt, nickel, and the like. The metal layer can be converted to form, in a subsequent heat treatment, a metal silicide compound with underlying silicon in the silicon substrate and/or in the gate electrode. The metal layer can be formed by any suitable technique, for example, CVD, physical vapor deposition (PVD), and the like. The metal layer can have any suitable thickness that depends on, for example, a desired thickness of the metal silicide formed in the subsequent process.

The metal layer can be converted to the metal silicides by heating the metal layer to cause a chemical reaction between the metal layer and the underlying silicon containing layer/component of the field effect transistor. In one embodiment, the metal silicides are formed by chemical reactions of the metal layer with the silicon of the underlying silicon substrate and/or with the polysilicon of the gate electrodes. During the silicidation process, the metal of the metal layer can diffuse into the underlying silicon containing layer/component and form the metal silicides. As a result, the metal silicides can be selectively formed on the field effect transistor.

The metal silicides can have any suitable height that depends on, for example, the desired implementations and/or the field effect transistor being fabricated. In one embodiment, the metal silicides have a height of about 5 nm or more and about 30 μm or less. In another embodiment, the metal silicides have a height of about 10 nm or more and about 25 μm or less.

Choice of suitable conditions and parameters (e.g., temperature, duration of heat treatment, and the like) of the silicidation process depends on, for example, the desirable dimensions (e.g., height) of the metal silicides, the configuration and/or constituent of the metal layer and/or the underlying silicon containing component/layer, the desired implementations and/or the field effect transistor being fabricated, and the like. For example, the metal silicides are formed by rapid thermal annealing (RTA).

Portions of the metal layer, for example, over the side spacer and the STIs remain unreacted and can be removed by, for example, etching. The unreacted portions of the metal layer can be removed by contacting the unreacted metal portions with any suitable metal etchant that does not substantially affect or damage the integrity of other layers/components of the field effect transistor such as the metal silicides. Examples of metal etchants include an oxidizing etchant solution. Examples of oxidizing etchants include an acidic solution containing, for example, H₂SO₄/H₂O₂, HNO₃/H₂O₂, HCl/H₂O₂, H₂O₂/NH₄OH/H₂O, H₃PO₄, HNO₃, CH₃COOH, and the like. Other metal etchants can also be used as long as they are capable of removing the unreacted portions of the metal layer selective to other components/layers of the field effect transistor.

The metal silicides can have a significantly lower sheet resistance than silicon and polysilicon. The metal silicides formed on the polysilicon containing gate is generally referred to as a polycide gate, which significantly reduces the resistance of the gate structure, as compared to a polysilicon gate. As a result, the overall conductivity of the gate electrode may be increased.

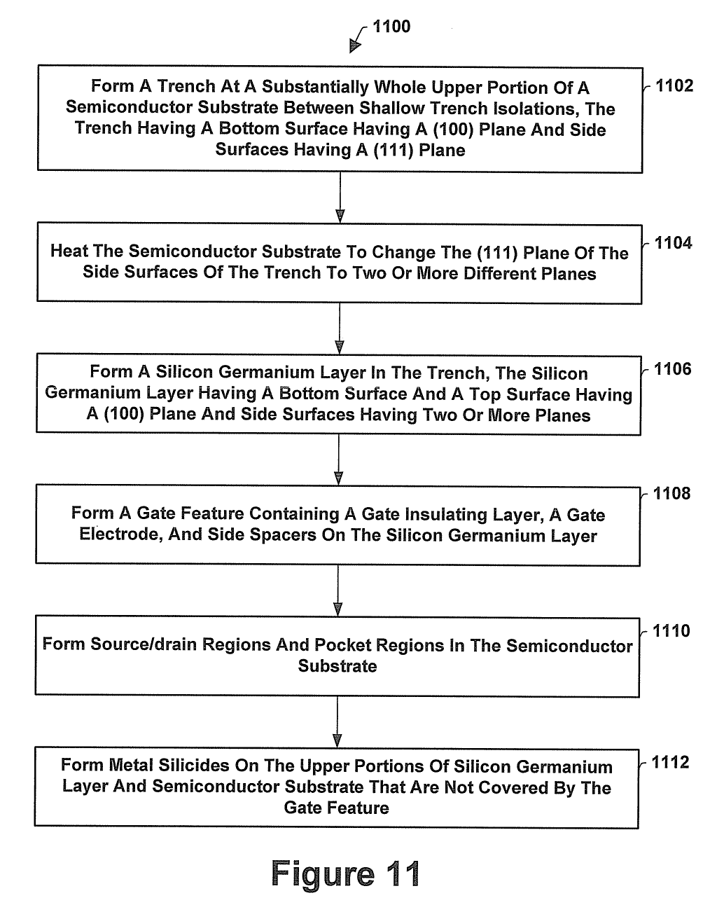

FIG. 11 illustrates an exemplary methodology 1100 of forming a field effect transistor. At 1102, a trench is formed at a substantially whole upper portion of a semiconductor substrate between shallow trench isolations, the trench having a (100) plane of a bottom surface and a (111) plane of side surfaces. At 1104, the semiconductor substrate is heated to change the (111) plane of the side surfaces of the trench to two or more different planes. At 1106, a silicon germanium layer is formed in the trench, the silicon germanium layer having a (100) plane of a bottom surface and a top surface and two or more planes of side surfaces. At 1108, a gate feature containing a gate insulating layer, a gate electrode, and side spacers is formed on the silicon germanium layer. At 1110, source/drain regions and pocket regions are formed in the semiconductor substrate. At 1112, metal silicides are formed on the upper portions of silicon germanium layer and semiconductor substrate that are not covered by the gate feature.

Although not shown in FIG. 11, the trench can be formed by an anisotropic chemical wet etching. In another embodiment, the trench is formed by using a tetramethylammonium hydroxide solution or an ammonium hydroxide solution. In yet another embodiment, the silicon germanium is formed by a silicon germanium epitaxial process. In still yet another embodiment, the (111) plane of the side surfaces of the trench is changed to two or more different planes by heating the semiconductor substrate in hydrogen at a temperature of about 700 degrees Celsius or more and about 1,300 degrees Celsius or less for about 5 minutes or more and about 100 minutes or less.

Although not shown in FIG. 11, contact holes, conductive lines, and other suitable components can be formed by any suitable semiconductor device fabrication processes. General examples of semiconductor device fabrication processes include masking, patterning, etching, cleaning, planarization, thermal oxidation, implantation, annealing, thermal treatment, and deposition techniques normally used for making semiconductor devices.

With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about.”

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims. Furthermore, to the extent that the term “contain,” “includes,” “has,” “involve,” or variants thereof is used in either the detailed description or the claims, such term can be inclusive in a manner similar to the term “comprising” as “comprising” is interpreted when employed as a transitional word in a claim.

What is claimed is:

1. A field effect transistor, comprising:
a semiconductor substrate comprising source/drain regions and pocket regions therein between shallow trench isolations;
a silicon germanium layer in a trench at an upper surface of the semiconductor substrate between the shallow trench isolations, the silicon germanium layer having a bottom surface and a top surface having a (100) plane and side surfaces having two or more planes;
a gate feature on the silicon germanium layer comprising a gate insulating layer, a gate electrode, and side spacers, the silicon germanium layer having no side surface under the gate feature in a direction of channel length; and
metal silicides on the upper portions of silicon germanium layer and semiconductor substrate that are not covered by the gate feature.

2. The field effect transistor of claim 1, wherein the trench has a bottom surface having a (100) plane and side surfaces having two or more planes.

3. The field effect transistor of claim 1, wherein the silicon germanium layer contains about 0 wt. % or more and about 80 wt. % or less of silicon and about 20 wt. % or more and about 100 wt. % of germanium.

4. The field effect transistor of claim 1, wherein the trench has no side surface at a portion of the semiconductor substrate that is covered with the gate feature in a direction of channel length.

5. The field effect transistor of claim 1, wherein the trench has all the side surfaces at portions of the semiconductor substrate that are not covered with the gate feature in a direction of channel length.

6. The field effect transistor of claim 1, wherein the silicon germanium layer has no side surface at a portion of the semiconductor substrate that is covered with the gate feature in a direction of channel length.

7. The field effect transistor of claim 1, wherein the silicon germanium has all the side surfaces at portions of the semiconductor substrate that are not covered with the gate feature in a direction of channel length.

8. A field effect transistor, comprising:
a semiconductor substrate comprising source/drain regions and pocket regions therein between shallow trench isolations;
a silicon germanium layer in a trench at a substantially whole upper surface of the semiconductor substrate between the shallow trench isolations, the silicon germanium layer having a bottom surface and a top surface having a (100) plane and side surfaces having two or more planes;
a gate feature on the silicon germanium layer comprising a gate insulating layer and a gate electrode, and side spacers; and
metal silicides on the upper portions of silicon germanium layer and semiconductor substrate that are not covered by the gate feature.

9. The field effect transistor of claim 8, wherein the trench has a bottom surface having a (100) plane and side surfaces having two or more planes.

10. The field effect transistor of claim 8, wherein the silicon germanium layer contains about 0 wt. %, or more and about 80 wt. % or less of silicon and about 20 wt. % or more and about 100 wt. % of germanium.

11. The field effect transistor of claim 8, wherein the trench has no side surface at a portion of the semiconductor substrate that is covered with the gate feature in a direction of channel length.

12. The field effect transistor of claim 8, wherein the trench has all the side surfaces at portions of the semiconductor substrate that are not covered with the gate feature in a direction of channel length.

13. The field effect transistor of claim 8, wherein the silicon germanium layer has no side surface at a portion of the semiconductor substrate that is covered with the gate feature in a direction of channel length.

14. The field effect transistor of claim 8, wherein the silicon germanium has all the side surfaces at portions of the semiconductor substrate that are not covered with the gate feature in a direction of channel length.

15. A method of forming a field effect transistor, comprising:
forming a trench at a substantially whole upper portion of a semiconductor substrate between shallow trench isolations, the trench having a bottom surface having a (100) plane and side surfaces having a (111) plane;
heating the semiconductor substrate to change the (111) plane of the side surfaces of the trench to two or more different planes;
forming a silicon germanium layer in the trench, the silicon germanium layer having a bottom surface and a top surface having a (100) plane and side surfaces having two or more planes;
forming a gate feature comprising a gate insulating layer, a gate electrode, and side spacers on the silicon germanium layer;
forming source/drain regions and pocket regions in the semiconductor substrate; and
forming metal silicides on the upper portions of silicon germanium layer and semiconductor substrate that are not covered by the gate feature.

16. The method of claim 15, wherein the trench is formed by an anisotropic chemical wet etching.

17. The method of claim 15, wherein the trench is formed by a tetramethylammonium hydroxide solution or an ammonium hydroxide solution.

18. The method of claim 15, wherein the silicon germanium is formed by a silicon germanium epitaxial process.

19. The method of claim 15, wherein the (111) plane of the side surfaces of the trench is changed to two or more different planes by heating the semiconductor substrate in hydrogen at a temperature of about 700 degrees Celsius or more and about 900 degrees Celsius or less for about 1 minutes or more and about 10 minutes or less.

20. The method of claim 15, wherein the silicon germanium layer has no side surface at a portion of the semiconductor substrate that is covered with the gate feature in a direction of channel length.
